(19) United States
(12) Patent Application Publication
(10) Pub. No.: US 2022/0336322 A1
(43) Pub. Date: Oct. 20, 2022

(54) TECHNOLOGIES FOR PACKAGE LOADING MECHANISMS

(71) Applicant: Intel Corporation, Santa Clara, CA (US)

(72) Inventors: Juha T. Paavola, Hillsboro, OR (US); Rob W. Sims, Forest Grove, OR (US); Alonso J. Rodriguez Chacon, Guacima (CR); Emery E. Frey, Portland, OR (US); Monica Maria Conejo Herrera, El Guarco (CR); Jerrod P. Peterson, Hillsboro, OR (US); Jose R. Diaz, Zapote (CR); Jose Guillermo Salazar Delgado, Puriscal (CR)

(73) Assignee: Intel Corporation, Santa Clara, CA (US)

(21) Appl. No.: 17/850,676

(22) Filed: Jun. 27, 2022

(51) Int. Cl. H01L 23/40; H01L 23/46; H05K 7/20; G06F 1/20

(52) U.S. Cl. CPC H01L 23/40; H01L 23/46; H05K 7/2049; G06F 1/203

(57) ABSTRACT

Techniques for package loading mechanisms are disclosed. In the illustrative embodiment, a base portion of a laptop includes a circuit board on which an integrated circuit component is mounted. A heat sink is mated with the integrated circuit component. A spring presses against part of the chassis of the laptop, pressing the integrated circuit component and the heat sink together, providing strong thermal coupling between them.

### BACKGROUND

Many integrated circuit components such as processors require heat sinks to operate in a safe temperature range. In order to ensure strong thermal coupling between the integrated circuit components and the heat sink, the integrated circuit components is pressed against the heat sink, such as by using spring screws pressing against the heat sink and screwing into a circuit board supporting the processor. Such an approach can require relatively large keep-out zones and can stress components, possibly leading to solder joint failure.

### BRIEF DESCRIPTION OF THE DRAWINGS

FIG. 1 is a simplified drawing of at least one embodiment of a compute device with a holeless spring loading mechanism.

FIG. 2 is a cross-sectional view of one embodiment of the base of the compute device of FIG. 1.

FIG. 3 is a cross-sectional view of one embodiment of an unloaded base of the compute device of FIG. 1.

FIG. 4 is a simplified drawing of one embodiment of a cover of the compute device of FIG. 1 with a spring loading mechanism.

FIG. 5 is a simplified drawing of one embodiment of a spring of the compute device of FIG. 1.

FIG. 6 is a top-down view of one embodiment of a spring of the compute device of FIG. 1.

FIG. 7 is a simplified drawing of one embodiment of a spring of the compute device of FIG. 1.

FIG. 8 is a top-down view of one embodiment of a spring of the compute device of FIG. 1.

FIG. 9 is a cross-sectional view of one embodiment of the base of the compute device of FIG. 1.

FIG. 10 is a top-down view of one embodiment of a spring and integrated circuit component of the compute device of FIG. 1.

FIG. 11 is a top-down view of one embodiment of a spring and integrated circuit component of the compute device of FIG. 1.

FIG. 12 is a top-down view of one embodiment of a spring and integrated circuit component of the compute device of FIG. 1.

FIG. 13 is a top-down view of one embodiment of a spring and integrated circuit component of the compute device of FIG. 1.

FIG. 14 is a simplified block diagram of at least one embodiment of the compute device of FIG. 1.

### DETAILED DESCRIPTION

In one illustrative embodiment, a compute device such as a laptop has a processor mounted on a circuit board. A heat sink is mated with the processor. The processor, circuit board, and heat sink may be in the base of the laptop, with part of the chassis above and below the circuit board, heat sink, and processor. In order to press the heat sink into the processor, a leaf spring presses against the chassis and against either the circuit board or the heat sink, pressing the heat sink and processor together, ensuring strong thermal contact.

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

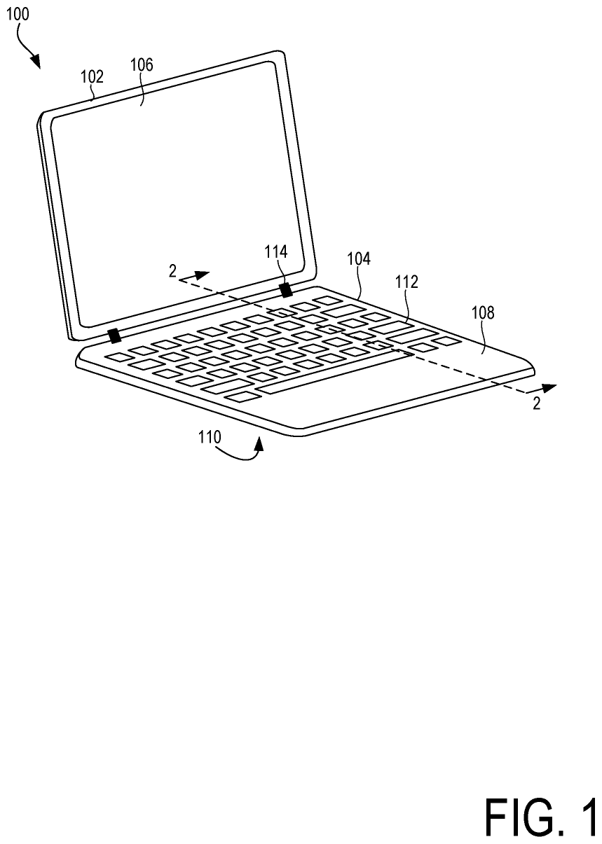

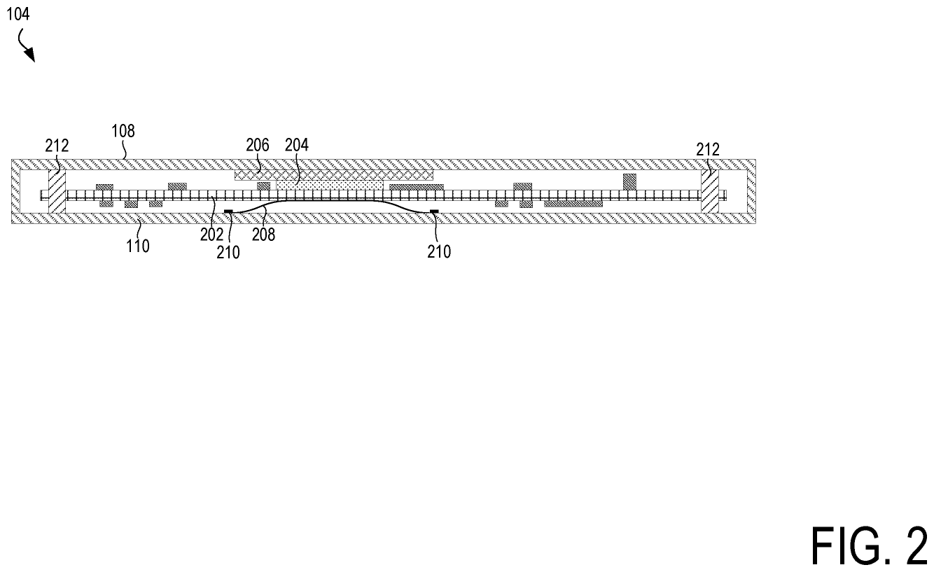

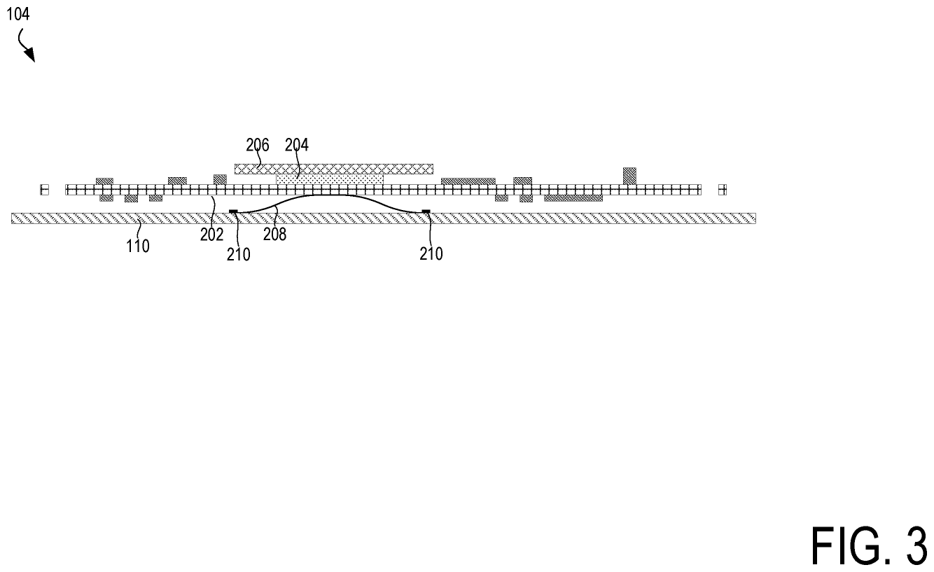

Referring now to FIG. 1, in one embodiment, a compute device 100 includes a display portion 102 and a base portion. FIG. 2 shows a cross-sectional view of the base portion 104. The base portion 104 of the compute device has a top cover 108 (which may be referred to as a C cover), a bottom cover 110 (which may be referred to as a D cover), and a keyboard 112. As shown in FIG. 2, inside of the base portion 104 is a circuit board 202, an integrated circuit component 204, and a heat sink 206. In the illustrative embodiment shown in FIG. 2, a spring 208 is mounted at mounting points 210 in the bottom cover 110. The spring 208 presses against the circuit board 202, on the opposite side from the integrated circuit component 204. The force from the spring 208 is transferred through the circuit board 202 to the integrated circuit component 204, pressing it against the heat sink 206. In the illustrative embodiment, the heat sink 206 is held in place by the top cover 108. The top cover 108 is attached to the bottom cover 110, such as by fasteners 212.

The illustrative configuration shown in FIG. 2 provides several advantages. The illustrative spring 208 is a leaf spring 208. As the leaf spring 208 is flattened under load, it applies a force through a relatively large contact area with the circuit board 202. The spring 208 can act as a backing plate, which can be particularly advantageous for thin circuit boards 202. The force applied by the spring 208 is near the center of the integrated circuit component 204, which may provide more even thermal coupling than applying a force at the edges. The spring 208 applies a compressive force with little or no stress on the solder balls located at the corners of the integrated circuit component 204, reducing or eliminating occurrence of corner solder ball solder joint failures due to stress applied to press the heat sink 206 into the integrated circuit component 204. The spring 208 does not require any holes through the circuit board 202, which can reduce or eliminate any keep-out zone (KOZ) on the side of the board with the integrated circuit component 204. As a result, other components may be placed closer to the integrated circuit component 204 and more area is available for routing signals, which can increase signal quality and/or bandwidth, reduce latency of communication between components, improve power efficiency, and potentially reduce the size of the circuit board 202. The spring 208 applies a compressive force with little or no stress, reducing or eliminating solder joint failure due to stress applied to press the heat sink 206 into the integrated circuit component 204. In some embodiments, the spring 208 can be installed without the use of any screws, simplifying the assembly process.

The illustrative compute device 100 is embodied as a laptop with a clamshell configuration. The illustrative compute device 100 can be in an open configuration (shown in FIG. 1) or a closed configuration, with the display portion 102 positioned on top of the base portion 104 with the display 106 facing downwards toward the base portion 104. Additionally or alternatively, the compute device 100 may be embodied as a laptop with additional configurations. For example, the compute device 100 may be a laptop with a display that can rotate up to 360°, allowing the compute device 100 to be in a book configuration, a tablet configuration, etc. The compute device 100 may be a 2-in-1 device, with a display portion 102 that can separate from the base portion 104. In some embodiments, the compute device 100 may be embodied as a tablet or other mobile device, with only a display portion 102 (including, e.g., a circuit board 202, integrated circuit component 204, heat sink 206, spring 208, etc.) and not a base portion 104.

The compute device 100 may include several components, such as a battery, one or more processors, a memory, one or more antennas (such as a Wi-Fi® antenna, a Bluetooth® antenna, a 5G antenna, a cellular antenna, etc.), a keyboard, one or more connectors (such as one or more USB2 connectors, one or more USB3 connectors, an SD card slot, a headphone and/or microphone jack, a power connector, etc.), etc. Each of those various components may be in the display portion 102 and/or the base portion 104.

The illustrative display portion 102 has a display 106. The display 106 may be any suitable size and/or resolution, such as a 5-18 inch display, with a resolution from 2340×480 to 3820×2400. The display 106 may use any suitable display technology, such as LED, OLED, QD-LED, etc. The display 106 may be a touchscreen display.

In the illustrative embodiment, the base portion 104 is connected to the display portion 102 by one or more hinges 114. The illustrative base portion 104 may include a keyboard 112, a mouse pad, a track pad, a touch pad, or other input devices. The top cover 108 and bottom cover 110 of the base portion 104 may be made of any suitable material, such as aluminum, steel, plastic, a combination of those materials, and/or the like.

The illustrative circuit board 202 may be made from ceramic, glass, and/or organic-based materials with fiberglass and resin, such as FR-4. The circuit board 202 may have any suitable length or width, such as 10-500 millimeters. The circuit board 110 may have any suitable thickness, such as 0.2-5 millimeters. The circuit board 202 may support additional components besides the integrated circuit component 204, such as additional integrated circuit components, a processor unit, a memory device, an accelerator device, etc.

In the illustrative embodiment, the integrated circuit component 204 is a processor. In other embodiments, the integrated circuit component 204 may be a different component, such as a memory, an accelerator device, a graphics processing unit, an application-specific integrated circuit (ASIC), a field-programmable gate array (FPGA), etc. In some embodiments, the compute device 100 may include more than one integrated circuit component 204. The additional integrated circuit component 204 may be pressed into a heat sink 206 (e.g., the same heat sink or a different heat sink) using another spring 108.

In the illustrative embodiment, the integrated circuit component 204 is connected to the circuit board 202 through a ball grid array. In other embodiments, the integrated circuit component 204 may be connected to the circuit board 202 through a land grid array, a pin grid array, etc. In the illustrative embodiment, the integrated circuit component 204 has an integrated heat spreader covering one or more dies. The integrated heat spreader spreads heat from the dies across the integrated heat spreader, and the heat is then transferred to the heat sink 106.

The heat sink 206 may be made of any suitable thermally conductive material. In the illustrative embodiment, the heat sink 206 is made of aluminum or copper. The heat sink 206 may be any type of heat sink, such as a vapor chamber, an air-cooled heat sink, a liquid-cooled heat sink, a heat pipe, etc. The heat sink 206 may include one or more fins or similar structure to increase an internal or external surface area. In the illustrative embodiment, a thermal interface material (TIM) is between the integrated circuit component 204 and the heat sink 206 to increase thermal coupling.

The spring 208 may be made of any suitable material. In the illustrative embodiment, the spring 208 may be made of, e.g., stainless steel or aluminum. The illustrative spring 208 is a leaf spring, with a length and/or width of, e.g., 5-50 millimeters. The spring 208 may have any suitable thickness, such as 0.1-2 millimeters. The spring 208 may apply any suitable force to the circuit board 202 (which is then transferred to the integrated circuit component 204), such as 2-30 pounds of force.

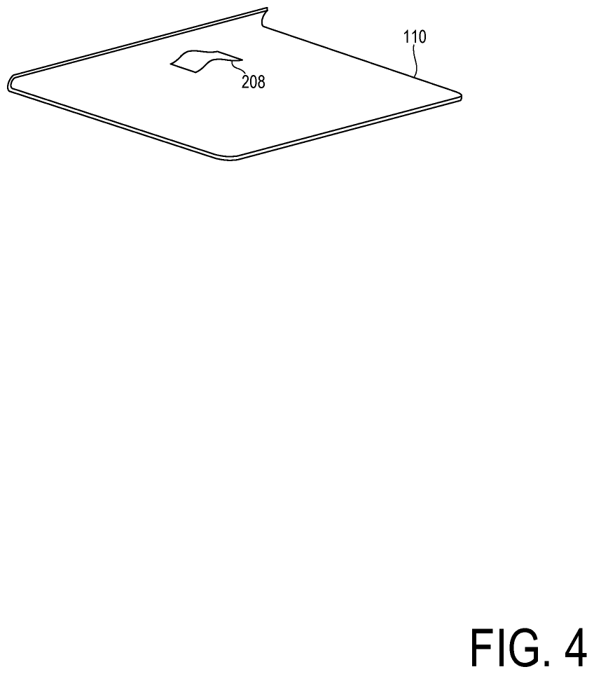

The mounting points 210 may be implemented in any suitable manner. For example, in one embodiment, the mounting points 210 are a slot into which some or all of an edge of the spring 208 can fit into, securing the spring 208 in place. In other embodiments, the spring 208 may be attached to the base portion 110 using, e.g., rivets, screws, adhesives, etc. In some embodiments, there may be thermal insulation between some or all of the spring 208 and the cover 110 to mitigate hot spots on the cover 110. In the illustrative embodiment, the spring 208 presses against the bottom cover 110. In other embodiments, the spring 208 may press against the top cover 108. As shown in FIG. 4, in one embodiment, spring 208 may be disposed in the bottom cover 110 of the compute device 100.

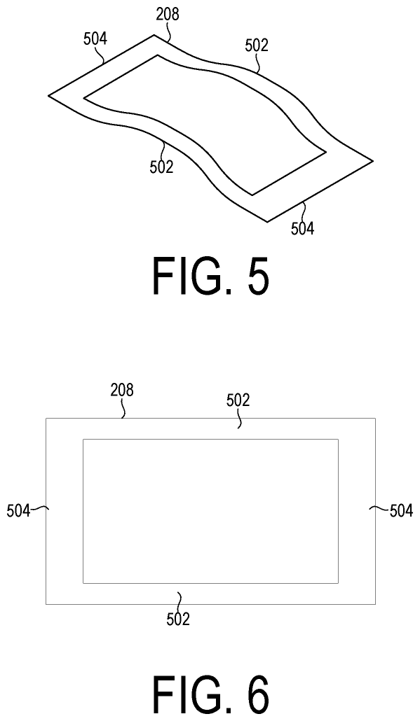

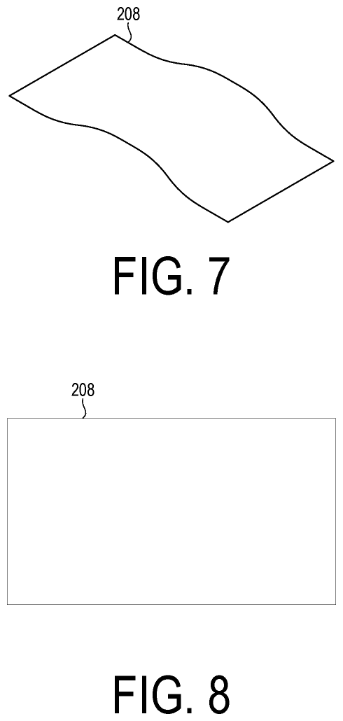

In one embodiment, the spring 208 may be embodied as a leaf spring 208 with two or more strips 502 that are connected by end strips 504, as shown in FIGS. 5 and 6. In use, the circuit board 202 presses down on the strips 502, deflecting them and causing the strips 502 to apply a force to the circuit board 202. In other embodiments, a single, broader strip may be used, as shown in FIGS. 7 and 8. In the illustrative embodiment, the leaf spring 208 has a single wave. In other embodiments, the leaf spring 208 may include more than one wave, and the spring 208 may, e.g,. compress each corner under the integrated circuit component 204.

In the illustrative embodiment, the spring 208 is a leaf spring, as described above. In other embodiments, the spring 208 may be embodied as any other suitable type of spring, such as a coil. In some embodiments, the spring 208 may be embodied as a strip of foam that, when compressed between, e.g., the circuit board 202 and the bottom cover 110, applies a force to the circuit board 202 below the integrated circuit component 204.

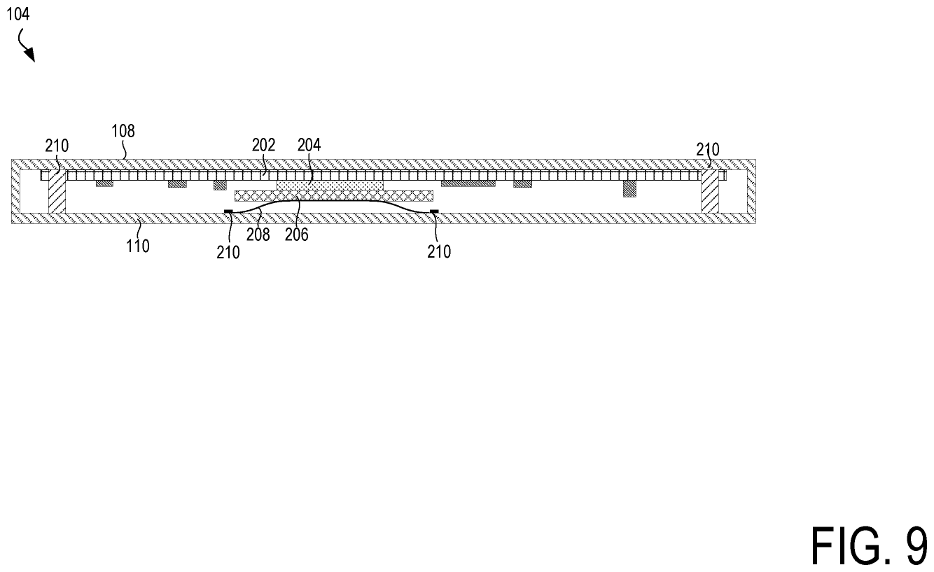

It should be appreciated that the configuration shown in FIG. 2 is merely one possible embodiment, and other embodiments are possible as well. For example, as shown in FIG. 9, in one embodiment, the spring 208 may press against the heat sink 206. The force is transferred from the heat sink 206 to the integrated circuit component 204, the circuit board 202, and the top cover 108.

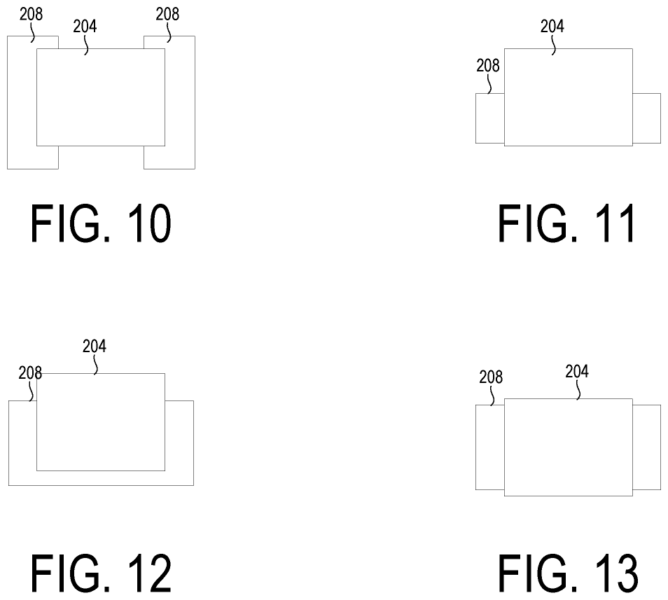

The spring 208 may be any suitable size and may be in any suitable position relative to the integrated circuit component. For example, FIGS. 10-13 show various configurations of the spring 208. FIGS. 10-13 show a top-down or bottom-up view without the circuit board 202, heat sink 206, or other components in the interest of clarity. In FIG. 10, two springs 208 apply a force to either side of the integrated circuit component 204. In FIG. 11, one small spring 208 is offset from the integrated circuit component 204. In FIG. 12, a large spring 208 is offset from the integrated circuit component 204. In FIG. 13, a large spring 208 is centered on the integrated circuit component 204.

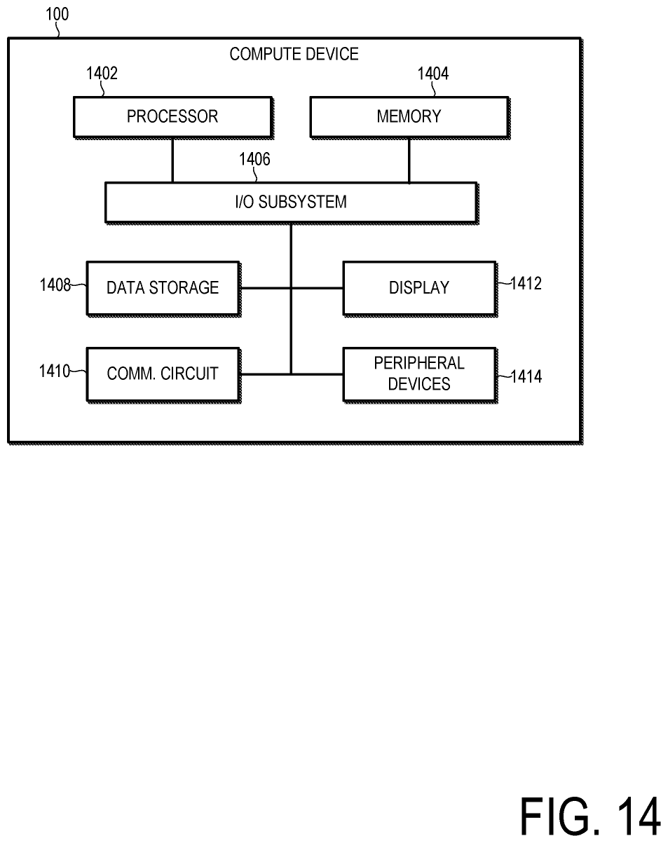

Referring now to FIG. 14, in one embodiment, a block diagram of various components of the compute device 100 are shown. The compute device 100 may be embodied as any type of compute device. For example, the compute device 100 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a network device, a router, a switch, a networked computer, a wearable computer, a handset, a messaging device, a camera device, and/or any other compute device. In some embodiments, the compute device 100 may be located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

The illustrative compute device 100 includes a processor 1402, a memory 1404, an input/output (I/O) subsystem 1406, data storage 1408, a communication circuit 1410, a display 1412, and one or more peripheral devices 1414. In some embodiments, one or more of the illustrative components of the compute device 100 may be incorporated in, or otherwise form a portion of, another component. For example, the memory 1404, or portions thereof, may be incorporated in the processor 1402 in some embodiments. In some embodiments, one or more of the illustrative components may be physically separated from another component.

The processor 1402 may be embodied as any type of processor capable of performing the functions described herein. For example, the processor 1402 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 1404 may be embodied as any type of volatile or non-volatile memory or data storage capable of performing the functions described herein. In operation, the memory 1404 may store various data and software used during operation of the compute device 100 such as operating systems, applications, programs, libraries, and drivers. The memory 1404 is communicatively coupled to the processor 1402 via the I/O subsystem 1406, which may be embodied as circuitry and/or components to facilitate input/output operations with the processor 1402, the memory 1404, and other components of the compute device 100. For example, the I/O subsystem 1406 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. The I/O subsystem 1406 may connect various internal and external components of the compute device 100 to each other with use of any suitable connector, interconnect, bus, protocol, etc., such as an SoC fabric, PCIe®, USB2, USB3, USB4, NVMe®, Thunderbolt®, and/or the like. In some embodiments, the I/O subsystem 1406 may form a portion of a system-on-a-chip (SoC) and be incorporated, along with the processor 1402, the memory 1404, and other components of the compute device 100 on a single integrated circuit chip.

The data storage 1408 may be embodied as any type of device or devices configured for the short-term or long-term storage of data. For example, the data storage 1408 may include any one or more memory devices and circuits, memory cards, hard disk drives, solid-state drives, or other data storage devices.

The communication circuit 1410 may be embodied as any type of interface capable of interfacing the compute device 100 with other compute devices, such as over one or more wired or wireless connections. In some embodiments, the communication circuit 1410 may be capable of interfacing with any appropriate cable type, such as an electrical cable or an optical cable. The communication circuit 1410 may be configured to use any one or more communication technology and associated protocols (e.g., Ethernet, Bluetooth®, Wi-Fi®, WiMAX, near field communication (NFC), etc.). The communication circuit 1410 may be located on silicon separate from the processor 1402, or the communication circuit 1410 may be included in a multi-chip package with the processor 1402, or even on the same die as the processor 1402. The communication circuit 1410 may be embodied as one or more add-in-boards, daughtercards, network interface cards, controller chips, chipsets, specialized components such as a field-programmable gate array (FPGA) or application-specific integrated circuit (ASIC), or other devices that may be used by the compute device 1402 to connect with another compute device. In some embodiments, communication circuit 1410 may be embodied as part of a system-on-a-chip (SoC) that includes one or more processors or included on a multichip package that also contains one or more processors. In some embodiments, the communication circuit 1410 may include a local processor (not shown) and/or a local memory (not shown) that are both local to the communication circuit 1410. In such embodiments, the local processor of the communication circuit 1410 may be capable of performing one or more of the functions of the processor 1402 described herein. Additionally or alternatively, in such embodiments, the local memory of the communication circuit 1410 may be integrated into one or more components of the compute device 1402 at the board level, socket level, chip level, and/or other levels.

The display 1412 may be embodied as any type of display on which information may be displayed to a user of the compute device 100, such as a touchscreen display, a liquid crystal display (LCD), a thin film transistor LCD (TFT-LCD), a light-emitting diode (LED) display, an organic light-emitting diode (OLED) display, a cathode ray tube (CRT) display, a plasma display, an image projector (e.g., 2D or 3D), a laser projector, a heads-up display, and/or other display technology. The display 1416 may have any suitable resolution, such as 7680×4320, 3840×2160, 1920×1200, 1920×1080, etc. In the illustrative embodiment, the display 1416 is the display 106.

In some embodiments, the compute device 100 may include other or additional components, such as those commonly found in a compute device. For example, the compute device 100 may also have peripheral devices 1414, such as a keyboard, a mouse, a speaker, an external storage device, a battery, etc. In some embodiments, the compute device 100 may be connected to a dock that can interface with various devices, including peripheral devices 1414.

### EXAMPLES

Illustrative examples of the technologies disclosed herein are provided below. An embodiment of the technologies may include any one or more, and any combination of, the examples described below.

Example 1 includes a compute device comprising a chassis; a circuit board; an integrated circuit component mounted on the circuit board; a heat sink mounted on the integrated circuit component; and a spring pressing against the chassis and pressing the heat sink and the integrated circuit component together.

Example 2 includes the subject matter of Example 1, and wherein the spring is a leaf spring.

Example 3 includes the subject matter of any of Examples 1 and 2, and wherein the spring is a coil spring.

Example 4 includes the subject matter of any of Examples 1-3, and wherein the spring is a strip of foam.

Example 5 includes the subject matter of any of Examples 1-4, and wherein the spring presses against the heat sink.

Example 6 includes the subject matter of any of Examples 1-5, and wherein the circuit board comprises a first side and second side, wherein the integrated circuit component is mounted on the first side of the circuit board, wherein the spring presses against the second side of the circuit board.

Example 7 includes the subject matter of any of Examples 1-6, and wherein the compute device is a laptop.

Example 8 includes the subject matter of any of Examples 1-7, and wherein the laptop comprises a display portion and a base portion, wherein the chassis comprises a bottom cover of the base portion, wherein the spring presses against the bottom cover of the base portion.

Example 9 includes the subject matter of any of Examples 1-8, and wherein the compute device is a tablet.

Example 10 includes the subject matter of any of Examples 1-9, and wherein the heat sink comprises a vapor chamber.

Example 11 includes the subject matter of any of Examples 1-10, and wherein the heat sink comprises a heat pipe.

Example 12 includes the subject matter of any of Examples 1-11, and wherein the spring does not require attachment holes passing through the circuit board.

Example 13 includes the subject matter of any of Examples 1-12, and wherein the circuit board comprises a first side and second side, wherein the integrated circuit component is mounted on the first side of the circuit board, wherein the spring does not require a keep-out zone on the first side of the circuit board.

Example 14 includes the subject matter of any of Examples 1-13, and wherein the integrated circuit component is a processor.

Example 15 includes a laptop comprising a display portion; a base portion, the base portion comprising a top cover and bottom cover; a circuit board disposed in the base portion; an integrated circuit component mounted on the circuit board; a heat sink mounted on the integrated circuit component; and a spring pressing against the bottom cover and pressing the heat sink and the integrated circuit component together.

Example 16 includes the subject matter of Example 15, and wherein the spring is a leaf spring.

Example 17 includes the subject matter of any of Examples 15 and 16, and wherein the spring is a coil spring.

Example 18 includes the subject matter of any of Examples 15-17, and wherein the spring is a strip of foam.

Example 19 includes the subject matter of any of Examples 15-18, and wherein the spring presses against the heat sink.

Example 20 includes the subject matter of any of Examples 15-19, and wherein the circuit board comprises a first side and second side, wherein the integrated circuit component is mounted on the first side of the circuit board, wherein the spring presses against the second side of the circuit board.

Example 21 includes the subject matter of any of Examples 15-20, and wherein the heat sink comprises a vapor chamber.

Example 22 includes the subject matter of any of Examples 15-21, and wherein the heat sink comprises a heat pipe.

Example 23 includes the subject matter of any of Examples 15-22, and wherein the spring does not require attachment holes passing through the circuit board.

Example 24 includes the subject matter of any of Examples 15-23, and wherein the circuit board comprises a first side and second side, wherein the integrated circuit component is mounted on the first side of the circuit board, wherein the spring does not require a keep-out zone on the first side of the circuit board.

Example 25 includes the subject matter of any of Examples 15-24, and wherein the integrated circuit component is a processor.

Example 26 includes a compute device comprising a chassis; a circuit board; an integrated circuit component mounted on the circuit board; a heat sink mounted on the integrated circuit component; and means for pressing the heat sink and the integrated circuit component together.

Example 27 includes the subject matter of Example 26, and wherein the means for pressing the heat sink and the integrated circuit component together comprises a leaf spring.

Example 28 includes the subject matter of any of Examples 26 and 27, and wherein the means for pressing the heat sink and the integrated circuit component together comprises a coil spring.

Example 29 includes the subject matter of any of Examples 26-28, and wherein the means for pressing the heat sink and the integrated circuit component together comprises a strip of foam.

Example 30 includes the subject matter of any of Examples 26-29, and wherein the means for pressing the heat sink and the integrated circuit component together presses against the heat sink.

Example 31 includes the subject matter of any of Examples 26-30, and wherein the circuit board comprises a first side and second side, wherein the integrated circuit component is mounted on the first side of the circuit board, wherein the means for pressing the heat sink and the integrated circuit component together presses against the second side of the circuit board.

Example 32 includes the subject matter of any of Examples 26-31, and wherein the compute device is a laptop.

Example 33 includes the subject matter of any of Examples 26-32, and wherein the laptop comprises a display portion and a base portion, wherein the chassis comprises a bottom cover of the base portion, wherein the means for pressing the heat sink and the integrated circuit component together presses against the bottom cover of the base portion.

Example 34 includes the subject matter of any of Examples 26-33, and wherein the compute device is a tablet.

Example 35 includes the subject matter of any of Examples 26-34, and wherein the heat sink comprises a vapor chamber.

Example 36 includes the subject matter of any of Examples 26-35, and wherein the heat sink comprises a heat pipe.

Example 37 includes the subject matter of any of Examples 26-36, and wherein the means for pressing the heat sink and the integrated circuit component together does not pass through holes in the circuit board.

Example 38 includes the subject matter of any of Examples 26-37, and wherein the circuit board comprises a first side and second side, wherein the integrated circuit component is mounted on the first side of the circuit board, wherein the means for pressing the heat sink and the integrated circuit component together does not require a keep-out zone on the first side of the circuit board.

Example 39 includes the subject matter of any of Examples 26-38, and wherein the integrated circuit component is a processor.

1. A compute device comprising:
a chassis;
a circuit board;
an integrated circuit component mounted on the circuit board;
a heat sink mounted on the integrated circuit component; and
a spring pressing against the chassis and pressing the heat sink and the integrated circuit component together.

2. The compute device of claim 1, wherein the spring is a leaf spring.

3. The compute device of claim 1, wherein the spring is a coil spring.

4. The compute device of claim 1, wherein the spring is a strip of foam.

5. The compute device of claim 1, wherein the spring presses against the heat sink.

6. The compute device of claim 1, wherein the circuit board comprises a first side and second side, wherein the integrated circuit component is mounted on the first side of the circuit board, wherein the spring presses against the second side of the circuit board.

7. The compute device of claim 1, wherein the compute device is a laptop.

8. The compute device of claim 7, wherein the laptop comprises a display portion and a base portion, wherein the chassis comprises a bottom cover of the base portion, wherein the spring presses against the bottom cover of the base portion.

9. The compute device of claim 1, wherein the compute device is a tablet.

10. The compute device of claim 1, wherein the heat sink comprises a vapor chamber.

11. The compute device of claim 1, wherein the heat sink comprises a heat pipe.

12. The compute device of claim 1, wherein the spring does not require attachment holes passing through the circuit board.

13. The compute device of claim 1, wherein the circuit board comprises a first side and second side, wherein the integrated circuit component is mounted on the first side of the circuit board, wherein the spring does not require a keep-out zone on the first side of the circuit board.

14. The compute device of claim 1, wherein the integrated circuit component is a processor.

15. A laptop comprising:
a display portion;
a base portion, the base portion comprising a top cover and bottom cover;
a circuit board disposed in the base portion;
an integrated circuit component mounted on the circuit board;
a heat sink mounted on the integrated circuit component; and
a spring pressing against the bottom cover and pressing the heat sink and the integrated circuit component together.

16. The laptop of claim 15, wherein the spring is a leaf spring.

17. The laptop of claim 15, wherein the spring presses against the heat sink.

18. The laptop of claim 15, wherein the circuit board comprises a first side and second side, wherein the integrated circuit component is mounted on the first side of the circuit board, wherein the spring presses against the second side of the circuit board.

19. The laptop of claim 15, wherein the spring does not require attachment holes passing through the circuit board.

20. A compute device comprising:
a chassis;
a circuit board;
an integrated circuit component mounted on the circuit board;
a heat sink mounted on the integrated circuit component; and
means for pressing the heat sink and the integrated circuit component together.

21. The compute device of claim 20, wherein the means for pressing the heat sink and the integrated circuit component together comprises a leaf spring.

22. The compute device of claim 20, wherein the means for pressing the heat sink and the integrated circuit component together comprises a strip of foam.

23. The compute device of claim 20, wherein the means for pressing the heat sink and the integrated circuit component together presses against the heat sink.

24. The compute device of claim 20, wherein the circuit board comprises a first side and second side, wherein the integrated circuit component is mounted on the first side of the circuit board, wherein the means for pressing the heat sink and the integrated circuit component together presses against the second side of the circuit board.

25. The compute device of claim 20, wherein the means for pressing the heat sink and the integrated circuit component together does not pass through holes in the circuit board.
